(19) United States
(12) Patent Application Publication
(10) Pub. No.: US 2025/0107384 A1
(43) Pub. Date: Mar. 27, 2025

(54) DISPLAY PANEL AND DISPLAY APPARATUS

(71) Applicants: Chengdu BOE Optoelectronics Technology Co., Ltd., Chengdu, Sichuan, (CN); BOE TECHNOLOGY GROUP CO., LTD., Beijing (CN)

(72) Inventors: Yangpeng WANG, Beijing (CN); Zhiying PIAO, Beijing (CN); Xucong WANG, Beijing (CN)

(21) Appl. No.: 18/577,227

(22) PCT Filed: Apr. 21, 2023
(86) PCT No.: PCT/CN2023/089711

§ 371 Date: Jan. 5, 2024

(51) Int. Cl. H10K 59/38; H10K 59/35

(52) U.S. Cl. CPC H10K 59/38; H10K 59/353

(57) ABSTRACT

A display panel, including a base, and pixel circuits, an array of pixel units, and a color filter layer sequentially stacked on a side of the base, where each pixel unit includes first and second subpixels, the first subpixel has an aperture ratio greater than that of the second subpixel, the first subpixel has more apertures than the second subpixel has, and the number of pixel circuit for driving the first subpixel is equal to the number of pixel circuit for driving the second subpixel; the color filter layer includes first and second color filters, orthographic projections of the first and second color filters on the base covers orthographic projections of the apertures in the first and second subpixels on the base, respectively; and the orthographic projections of the first and second color filters on the base each have a shape, at least part of edges of which are curved.

### TECHNICAL FIELD

Embodiments of the present disclosure belong to the field of display technology, and specifically relate to a display panel and a display apparatus.

### BACKGROUND

Due to the advantages of self-luminescence, low power consumption, lightness, thinness, flexibility, gorgeous color, high contrast, and fast response, the organic light-emitting diode (OLED) display screen has gained wide attention and seemingly become a representative of the next generation display, gradually replacing the liquid crystal display (LCD) screen.

### SUMMARY

In a first aspect, an embodiment of the present disclosure provides a display panel, including a base, pixel circuits, an array of pixel units, and a color filter layer, wherein
the pixel circuits, the array of pixel units, and the color filter layer are sequentially stacked on a side of the base;
each pixel unit includes a first subpixel and a second subpixel, the first subpixel has an aperture ratio greater than an aperture ratio of the second subpixel, the first subpixel has more apertures than the second subpixel has, and the number of pixel circuit for driving the first subpixel is equal to the number of pixel circuit for driving the second subpixel;
the color filter layer includes a first color filter and a second color filter, an orthographic projection of the first color filter on the base covers an orthographic projection of the aperture in the first subpixel on the base, and an orthographic projection of the second color filter on the base covers an orthographic projection of the aperture in the second subpixel on the base; and
the orthographic projections of the first color filter and the second color filter on the base each have a shape, at least part of edges of which are curved.

In some embodiments, the pixel unit further includes a third subpixel,
the first subpixel has an aperture ratio greater than an aperture ratio of the third subpixel, the first subpixel has more apertures than the third subpixel has, and the number of pixel circuit for driving the first subpixel is equal to the number of pixel circuit for driving the third subpixel;
the color filter layer further includes a third color filter, and an orthographic projection of the third color filter on the base covers an orthographic projection of the aperture in the third subpixel on the base; and
the orthographic projection of the third color filter on the base has a shape, at least part of edges of which are curved.

In some embodiments, for the shape of the orthographic projection of the first color filter on the base, a ratio of a dimension in a row direction of the array of pixel units to a dimension in a column direction of the array of pixel units is in a range of 0.8 to 1.2;
for the shape of the orthographic projection of the second color filter on the base, a ratio of a dimension in the row direction of the array of pixel units to a dimension in the column direction of the array of pixel units is in a range of 0.8 to 1.2; and
for the shape of the orthographic projection of the third color filter on the base, a ratio of a dimension in the row direction of the array of pixel units to a dimension in the column direction of the array of pixel units is in a range of 0.8 to 1.2.

In some embodiments, the shape of the orthographic projection of the first color filter on the base is symmetrical in both a row direction and a column direction of the array of pixel units;
the shape of the orthographic projection of the second color filter on the base is symmetrical in both the row direction and the column direction of the array of pixel units; and
the shape of the orthographic projection of the third color filter on the base is symmetrical in both the row direction and the column direction of the array of pixel units.

In some embodiments, the orthographic projection of the aperture in the first subpixel on the base has the same shape as the orthographic projection of the first color filter on the base;
the orthographic projection of the aperture in the second subpixel on the base has the same shape as the orthographic projection of the second color filter on the base; and
the orthographic projection of the aperture in the third subpixel on the base has the same shape as the orthographic projection of the third color filter on the base.

In some embodiments, the first subpixel has two apertures;
the second subpixel has one aperture;
the third subpixel has one aperture;
in each pixel unit, the second subpixel and the third subpixel are arranged in a first direction, the second subpixel and the first subpixel are arranged in a second direction, and the third subpixel and the first subpixel are arranged in the second direction;
in each pixel unit, the two apertures in the first subpixel are arranged in the first direction; and
the first direction is a column direction of the array of pixel units, and the second direction is a row direction of the array of pixel units.

In some embodiments, the aperture in the second subpixel and one aperture in the first subpixel are adjacent to each other and located in a first row, and the aperture in the third subpixel and the other aperture in the first subpixel are adjacent to each other and located in a second row; and
the first row is adjacent to the second row, the aperture in the second subpixel and the aperture in the third subpixel are located in the same column, and the one aperture in the first subpixel and the other aperture in the first subpixel are located in the same column.

In some embodiments, the aperture in the second subpixel is in a first row, the aperture in the third subpixel and one aperture in the first subpixel are adjacent to each other and located in a second row, and the other aperture is in the first subpixel in a third row; and
the first row, the second row, and the third row are sequentially arranged in the first direction, the aperture in the second subpixel and the aperture in the third subpixel are located in the same column, and the one aperture in the first subpixel and the other aperture in the first subpixel are located in the same column.

In some embodiments, in an odd column of the pixel units, the aperture in the second subpixel is in a first row, the aperture in the third subpixel and one aperture in the first subpixel are adjacent to each other and located in a second row, and the other aperture in the first subpixel is in a third row; and
the first row, the second row, and the third row are sequentially arranged in the first direction, the aperture in the second subpixel and the aperture in the third subpixel are located in the same column, and the one aperture in the first subpixel and the other aperture in the first subpixel are located in the same column;
in an even column of the pixel units, the aperture in the second subpixel and one aperture in the first subpixel are adjacent to each other and located in a first row, and the aperture in the third subpixel and the other aperture in the first subpixel are adjacent to each other and located in a second row; and
the first row is adjacent to the second row, the aperture in the second subpixel and the aperture in the third subpixel are located in the same column, and the one aperture in the first subpixel and the other aperture in the first subpixel are located in the same column.

In some embodiments, the first subpixel includes a first anode;
the first anode includes a first main body part and a first connection part, and the first main body part is electrically connected to the first connection part which is further electrically connected to the pixel circuit for the first subpixel;
the second subpixel includes a second anode;
the second anode includes a second body part and a second connection part, and the second main body part is electrically connected to the second connection part which is further electrically connected to the pixel circuit for the second subpixel;
the third subpixel includes a third anode;
the third anode includes a third main body part and a third connection part, and the third main body part is electrically connected to the third connection part which is further electrically connected to the pixel circuit for the third subpixel;
an orthographic projection of the first main body part on the base has a shape the same as or similar to the shape of the orthographic projection of the first color filter on the base;
an orthographic projection of the second main body part on the base has a shape the same as or similar to the shape of the orthographic projection of the second color filter on the base; and
an orthographic projection of the third main body part on the base has a shape the same as or similar to the shape of the orthographic projection of the third color filter on the base.

In some embodiments, the first subpixel, the second subpixel, and the third subpixel are different in color,
the apertures in the first subpixel have different areas;
a shortest distance between aperture outlines of the aperture in the first subpixel and the aperture in the second subpixel adjacent to each other in the pixel unit is greater than 10 μm; and a shortest distance between aperture outlines of the aperture in the second subpixel and the aperture in the third subpixel adjacent to each other in the pixel unit is greater than 10 μm.

In some embodiments, outlines on the same side of the aperture in the second subpixel and one aperture in the first subpixel in the same row as the aperture in the second subpixel in the pixel unit are on a first straight line,
outlines on the same side of the aperture in the third subpixel and the other aperture in the first subpixel in the same row as the aperture in the third subpixel in the pixel unit are on a second straight line,
outlines on the same side of the aperture in the second subpixel and the aperture in the third subpixel in the same column as the aperture in the second subpixel in the pixel unit are on a third straight line,
outlines on the same side of the one aperture in the first subpixel and the other aperture in the first subpixel in the same column as the one aperture in the first subpixel in the pixel unit are on a fourth straight line,
the first straight line, the second straight line, the third straight line, and the fourth straight line are spliced to form a rectangle, and
orthographic projections of the two apertures in the first subpixel, the aperture in the second subpixel, and the aperture in the third subpixel in the pixel unit on the base are within an orthographic projection of the rectangle on the base.

In some embodiments, centers of the aperture in the second subpixel and one aperture in the first subpixel in the same row as the aperture in the second subpixel in the pixel unit are on a first straight line,
centers of the aperture in the third subpixel and the other aperture in the first subpixel in the same row as the aperture in the third subpixel in the pixel unit are on a second straight line,
centers of the aperture in the second subpixel and the aperture in the third subpixel in the same column as the aperture in the second subpixel in the pixel unit are on a third straight line,
centers of the one aperture in the first subpixel and the other aperture in the first subpixel in the same column as the one aperture in the first subpixel in the pixel unit are on a fourth straight line, and
the first straight line, the second straight line, the third straight line, and the fourth straight line are spliced to form a rectangle.

In some embodiments, the first subpixel includes a blue subpixel;
the second subpixel includes a green subpixel;
the third subpixel includes a red subpixel;
the first subpixel has an aperture area greater than an aperture area of the second subpixel, and the second subpixel has an aperture area greater than an aperture area of the third subpixel;
a ratio of the aperture area of the second subpixel to the aperture area of the first subpixel in the pixel unit is greater than or equal to 1:3 and less than 1:1: and
a ratio of an area of the aperture in the third subpixel to an area of any aperture in the first subpixel in the pixel unit is greater than or equal to 1:3 and less than 1:0.

In some embodiments, the first subpixel includes a green subpixel;
the second subpixel includes a blue subpixel;
the third subpixel includes a red subpixel;
the first subpixel has an aperture area greater than an aperture area of the second subpixel, and the second subpixel has an aperture area greater than an aperture area of the third subpixel;
a ratio of the aperture area of the second subpixel to the aperture area of the first subpixel in the pixel unit is greater than or equal to 1:3 and less than 1:1; and
a ratio of an area of the aperture in the third subpixel to an area of any aperture in the first subpixel in the pixel unit is greater than or equal to 1:3 and less than 1:0.

In some embodiments, the first subpixel includes a first anode; and
first anodes corresponds to all apertures in the first subpixel in the pixel unit and has a one-piece structure.

In some embodiments, the pixel circuit includes a first connecting electrode,
the first connecting electrode is on a side of the first anode close to the base; a first planarization layer is between the first connecting electrode and the first anode;
an orthographic projection of the first connecting electrode on the base is at least partially overlapped with an orthographic projection of the first anode on the base, and the first planarization layer is provided with a first via in an overlap region of the orthographic projections, and the first anode is connected to the first connecting electrode through the first via; and
an orthographic projection of the first via on the base is not overlapped with the orthographic projection of the aperture in the first subpixel on the base.

In some embodiments, the first subpixel includes a first anode;
the first anode includes a plurality of sub-electrodes distributed at intervals; and
orthographic projections of the apertures in the first subpixel in the pixel unit on the base are respectively within orthographic projections of different sub-electrodes on the base.

In some embodiments, the pixel circuit includes a first connecting electrode and a second connecting electrode,
the first connecting electrode and the second connecting electrode are in the same layer;
the first connecting electrode and the second connecting electrode are on a side of the first anode close to the base; a first planarization layer is between the first anode and the first and second connecting electrodes;
an orthographic projection of the first connecting electrode on the base is at least partially overlapped with an orthographic projection of one sub-electrode of the first anode on the base, and the first planarization layer is provided with a first via in an overlap region of the orthographic projections, and the one sub-electrode of the first anode is connected to the first connecting electrode through the first via;
an orthographic projection of the first via on the base is not overlapped with the orthographic projection of the aperture in the first subpixel on the base;
an orthographic projection of the second connecting electrode on the base is at least partially overlapped with orthographic projections of any two adjacent sub-electrodes of the first anode on the base, and the first planarization layer is further provided with a second via in an overlap region of the orthographic projections, and the two adjacent sub-electrodes of the first anode are respectively connected to the second connecting electrode through the second via; and
an orthographic projection of the second via on the base is not overlapped with the orthographic projection of the aperture in the first subpixel on the base.

In some embodiments, the orthographic projection of the second connecting electrode on the base is located between the orthographic projections of the two adjacent sub-electrodes of the first anode on the base, and
at least a part of the orthographic projection of the second connecting electrode on the base is not overlapped with the orthographic projections of the two adjacent sub-electrodes of the first anode on the base.

In some embodiments, the orthographic projections of the first via and the second via on the base are within an orthographic projection of the pixel circuit for the first subpixel on the base.

In some embodiments, the pixel circuit further includes a first drive transistor,
the first drive transistor is on a side of the first connecting electrode close to the base, and a second planarization layer is between the first drive transistor and the first connecting electrode;
the orthographic projection of the first connecting electrode on the base is at least partially overlapped with an orthographic projection of a first electrode of the first drive transistor on the base, and the second planarization layer is provided with a third via in an overlap region of the orthographic projections, and the first connecting electrode is connected to the first electrode of the first drive transistor through the third;
an orthographic projection of the third via on the base is not overlapped with the orthographic projection of the aperture in the first subpixel on the base.

In some embodiments, the second subpixel includes a second anode;
the pixel circuit further includes a third connecting electrode,
the third connecting electrode and the first connecting electrode are in the same layer;
the third connecting electrode is on a side of the second anode close to the base; the first planarization layer further extends between the third connecting electrode and the second anode;
an orthographic projection of the third connecting electrode on the base is at least partially overlapped with an orthographic projection of the second anode on the base, and the first planarization layer is further provided with a fourth via in an overlap region of the orthographic projections, and the second anode is connected to the third connecting electrode through the fourth via;
an orthographic projection of the fourth via on the base is not overlapped with an orthographic projection of the aperture in the second subpixel on the base;
the third subpixel includes a third anode;
the pixel circuit further includes a fourth connecting electrode,
the fourth connecting electrode and the first connecting electrode are in the same layer;
the fourth connecting electrode is on a side of the third anode close to the base; the first planarization layer further extends between the fourth connecting electrode and the third anode;
an orthographic projection of the fourth connecting electrode on the base is at least partially overlapped with an orthographic projection of the third anode on the base, and the first planarization layer is further provided with a fifth via in an overlap region of the orthographic projections, and the third anode is connected to the fourth connecting electrode through the fifth via; and
an orthographic projection of the fifth via on the base is not overlapped with an orthographic projection of the aperture in the third subpixel on the base.

In some embodiments, the orthographic projection of the fourth via on the base is within an orthographic projection of the pixel circuit for the second subpixel on the base; and
the orthographic projection of the fifth via on the base is within an orthographic projection of the pixel circuit for the third subpixel on the base.

In some embodiments, the pixel circuit further includes a second drive transistor,
the second drive transistor is on a side of the third connecting electrode close to the base, and the second planarization layer further extends between the second drive transistor and the third connecting electrode;
the orthographic projection of the third connecting electrode on the base is at least partially overlapped with an orthographic projection of a first electrode of the second drive transistor on the base, and the second planarization layer is further provided with a sixth via in an overlap region of the orthographic projections, and the third connecting electrode is connected to the first electrode of the second drive transistor through the sixth via;
an orthographic projection of the sixth via on the base is not overlapped with an orthographic projection of the aperture in the second subpixel on the base;
the pixel circuit further includes a third drive transistor,
the third drive transistor is on a side of the fourth connecting electrode close to the base, and the second planarization layer further extends between the third drive transistor and the fourth connecting electrode;
the orthographic projection of the fourth connecting electrode on the base is at least partially overlapped with an orthographic projection of a first electrode of the third drive transistor on the base, and the second planarization layer is further provided with a seventh via in an overlap region of the orthographic projections, and the fourth connecting electrode is connected to the first electrode of the third drive transistor through the seventh via; and
an orthographic projection of the seventh via on the base is not overlapped with an orthographic projection of the aperture in the third subpixel on the base.

In some embodiments, the orthographic projections of the first, second and third color filters on the base are not overlapped with each other; and
the color filter layer further includes a black matrix having a pattern complementary to patterns of the first, second and third color filters.

In some embodiments, the display panel further includes an encapsulation layer, a touch layer, and a cover plate, wherein
the encapsulation layer and the touch layer are located between the array of pixel units and the color filter layer, and sequentially stacked on a side of the array of pixel units close to the color filter layer; and
the cover plate is on a side of the color filter layer away from the base.

An embodiment of the present disclosure further provides a display apparatus, including the display panel as described above.

### BRIEF DESCRIPTION OF DRAWINGS

Accompanying drawings are provided for further understanding of the embodiments of the present disclosure and constitute a part of the specification. Hereinafter, these drawings are intended to explain the present disclosure together with the following embodiments, but should not be considered as a limitation to the present disclosure. The above and other features and advantages will become more apparent to those skilled in the art by describing in detail example embodiments thereof with reference to the attached drawings, in which:

FIG. 1a is a schematic structural top view of a display panel in the existing art.

FIG. 1b is a schematic structural sectional view taken along line AA in FIG. 1a.

FIG. 1c is another schematic structural sectional view taken along line AA in FIG. 1a.

FIG. 1d is yet another schematic structural sectional view taken along line AA in FIG. 1a.

FIG. 1e is a schematic top view of a subpixel structure in a display panel in the existing art.

FIG. 2a is a schematic structural top view of a display panel according to an embodiment of the present disclosure.

FIG. 2b is a schematic structural top view of another display panel according to an embodiment of the present disclosure.

FIG. 2c is a schematic structural sectional view taken along line BB in FIG. 2b.

FIG. 2d is a schematic structural top view of yet another display panel according to an embodiment of the present disclosure.

FIG. 2e is a schematic structural top view of yet another display panel according to an embodiment of the present disclosure.

FIG. 2f is a schematic structural top view of yet another display panel according to an embodiment of the present disclosure.

FIG. 2g is a schematic structural top view of yet another display panel according to an embodiment of the present disclosure.

FIG. 2h is a schematic structural top view of yet another display panel according to an embodiment of the present disclosure.

FIG. 2i is a schematic structural top view of yet another display panel according to an embodiment of the present disclosure.

FIG. 2j is a schematic structural top view of yet another display panel according to an embodiment of the present disclosure.

FIG. 2k is a schematic structural top view of yet another display panel according to an embodiment of the present disclosure.

FIG. 2l is a schematic structural sectional view taken along line CC in FIG. 2k.

FIG. 2m is a schematic structural sectional view taken along line DD in FIGS. 2b and 2k.

### DETAIL DESCRIPTION OF EMBODIMENTS

In order to make those skilled in the art better understand the technical solutions in the embodiments of the present disclosure, the display panel and the display apparatus provided in the embodiments of the present disclosure will be described in further detail below with reference to the accompanying drawings and specific implementations.

Embodiments of the present disclosure will be described more sufficiently below with reference to the accompanying drawings, which may be embodied in different forms and should not be construed as being limited to the embodiments set forth herein. Rather, these embodiments are provided so that the present disclosure will be thorough and complete, and will fully convey the scope of the present disclosure to those skilled in the art.

The embodiments of the present disclosure are not limited to the embodiments shown in the drawings, but further include modifications of configurations formed based on a manufacturing process. Thus, the regions illustrated in the figures have schematic properties, and the shapes of the regions shown in the figures illustrate specific shapes of regions, but are not intended to be limitative.

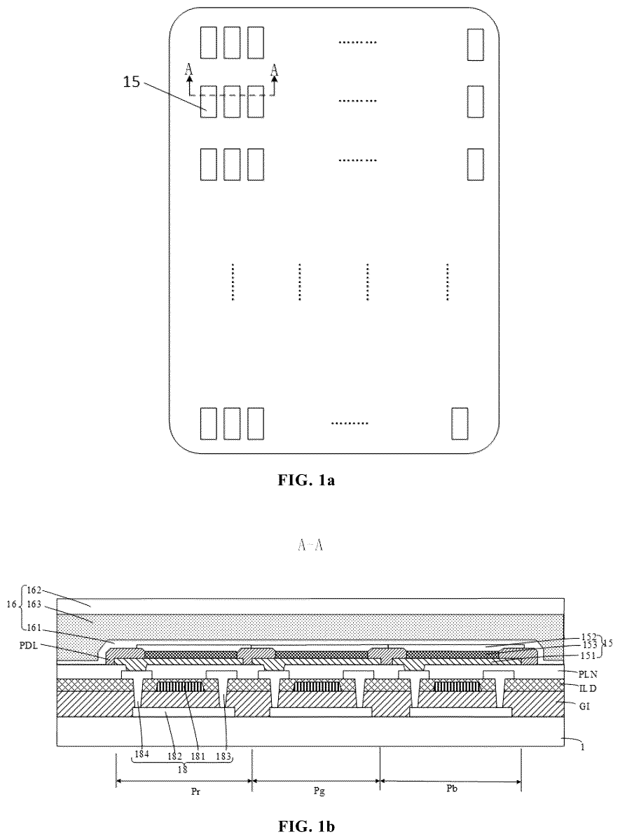

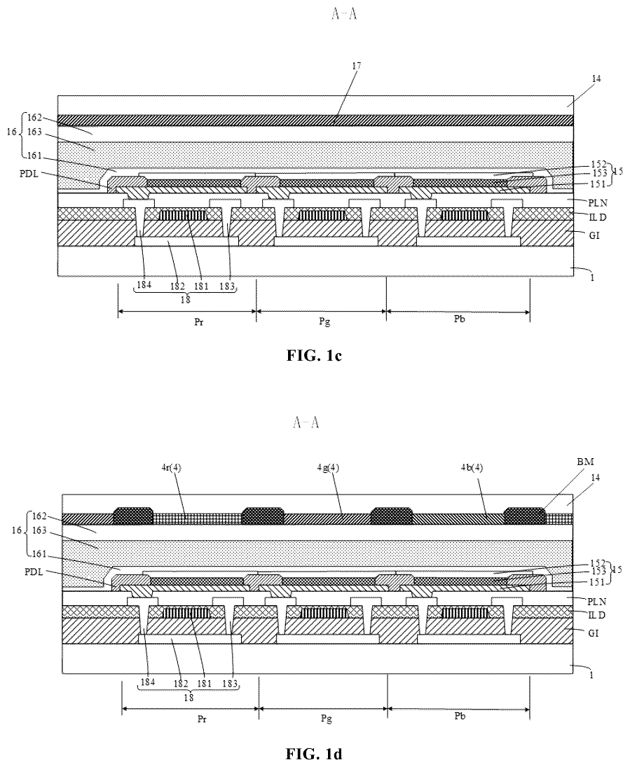

FIG. 1a shows a schematic structural top view of a display panel in the existing art, and FIG. 1b is a schematic structural sectional view taken along line AA in FIG. 1a. As shown in the figures, the display panel in the existing art includes a drive substrate, a plurality of light-emitting devices 15 on the drive substrate, and an encapsulation structure 16 that encapsulates the plurality of light-emitting devices 15. The display panel has a plurality of subpixel regions of different colors, including, for example, a red subpixel region Pr, a green subpixel region Pg, and a blue subpixel region Pb. The plurality of light-emitting devices 15 have different colors, and a light-emitting device 15 of a certain color corresponds to a subpixel region of the corresponding color. For example, a light-emitting device emitting red light is located in the red subpixel region Pr, a light-emitting device emitting green light is located in the green subpixel region Pg, and a light-emitting device emitting blue light is located in the blue subpixel region Pb.

The drive substrate includes a base 1, and a drive structure layer on the base 1. The plurality of light-emitting devices 15, and the encapsulation structure 16 that encapsulates the plurality of light-emitting devices 15, are sequentially disposed on the drive structure layer. The drive structure layer may include pixel drive circuits for driving the light-emitting devices 15 to emit light. Each of the light-emitting devices 15 may include a first electrode 151, a second electrode 152, and an emission functional layer 153 between the first electrode 151 and the second electrode 152. The first electrode 151 may serve as an anode of the light-emitting device 15, the second electrode 152 may serve as a cathode of the light-emitting device 15, and when a current is generated between the first electrode 151 and the second electrode 152, the emission functional layer 153 emits light. The emission functional layer 153 may include a hole injection layer, a hole transport layer, an emission layer, an electron transport layer, and an electron injection layer sequentially stacked together. Optionally, the light-emitting device 15 is an organic light-emitting diode (OLED) device, and in this case, the emission layer includes an organic light-emitting material.

In some embodiments, the first electrode 151 is a reflective electrode configured to reflect light emitted onto the first electrode 151; and the second electrode 152 is configured to partially transmit and partially reflect light emitted onto the second electrode 152.

In some embodiments, referring to FIG. 1b, the drive structure layer includes a plurality of pixel drive circuits in one-to-one correspondence with the light-emitting devices 15 and configured to provide drive currents for the light-emitting devices 15 to drive the light-emitting devices 15 to emit light. For example, the pixel driving circuit includes a plurality of thin film transistors 18. Each thin film transistor 18 includes a gate 181, an active layer 182, a source 183 and a drain 184. Taking the thin film transistor 18 being a top gate type thin film transistor as an example, the active layer 182 is located between the gate 181 and the base 1; a gate insulation layer GI is disposed on a side of the active layer 182 away from the base 1; the gate 181 is disposed on a side of the gate insulation layer GI away from the base 1; and an interlayer insulation layer ILD is disposed on a side of the gate 181 away from the base 1, with the source 183 and the drain 184 arranged in the same layer on a side of the interlayer insulation layer ILD away from the base 1, and respectively electrically connected to the active layer 182. A planarization layer PLN is disposed on a side of the source 183 and the drain 184 away from the base 1. A pixel defining layer PDL with a plurality of pixel apertures is on a side of the planarization layer PLN away from the base 1. The light-emitting devices 15 are in one-to-one correspondence with the pixel apertures, and each include a first electrode 151, a second electrode 152, and an emission functional layer 153 between the first electrode 151 and the second electrode 152. For example, the first electrode 151 is an anode, and the second electrode 152 is a cathode. The first electrode 151 is disposed between the pixel defining layer PDL and the planarization layer PLN, and has a portion exposed from the pixel apertures.

In some embodiments, the encapsulation structure 16 includes a first inorganic encapsulation layer 161, a second inorganic encapsulation layer 162, and an organic encapsulation layer 163 therebetween. The first inorganic encapsulation layer 161, the organic encapsulation layer 163, and the second inorganic encapsulation layer 162 are sequentially stacked to encapsulate the plurality of light-emitting devices 15, thereby preventing moisture and/or oxygen in the external environment from corroding the light-emitting devices 15. Both the first inorganic encapsulation layer 161 and the second inorganic encapsulation layer 162 may be made of an inorganic material with high compactness, and the organic encapsulation layer 163 may be made of an organic polymer resin material.

In the existing art, a complex pixel drive circuit is typically provided in the display panel. In order to improve the emission efficiency and reduce the power consumption of the display panel, an anode being a total reflection electrode and a cathode being a transflective electrode are used in combination, which may lead to a very high reflectivity of the drive substrate. In order to reduce the reflectivity, an attached polarizer is used in the existing art. Referring to FIG. 1c, another schematic structural sectional view taken along line AA of FIG. 1a is shown. A polarizer 17 is attached to a side of the encapsulation structure 16 away from the base 1 to reduce the reflectivity of the drive substrate. However, attachment of the polarizer 17 notably reduces light transmittance of the display panel. In some embodiments, a cover plate 14 is provided on a side of the polarizer 17 away from the base 1.

In some embodiments, referring to FIG. 1d, yet another schematic structural sectional view taken along line AA of FIG. 1a is shown. In order not to reduce the light transmittance of the display panel, a color filter layer 4 is used in place of the polarizer. The color filter layer 4 includes a plurality of color filter parts 4r, 4g and 4b, each of which corresponds to one of the light-emitting devices 15 and emits light of the same color as the corresponding light-emitting device 15. For example, the color filter part 4r is red and corresponds to a red light-emitting device; the color filter part 4g is green and corresponds to a green light-emitting device; and the color filter part 4b is blue and corresponds to a blue light-emitting device. The color filter layer further includes a black matrix BM disposed in the same layer as the plurality of color filter parts 4r, 4g, and 4b and having a complementary shape to the plurality of color filter parts 4r, 4g, and 4b. In some embodiments, a cover plate 14 is provided on a side of the color filter layer 4 away from the base 1.

In some embodiments, some requirements on shapes of the subpixels in the display panel (i.e., a shape of an effective light-emitting region of the light-emitting device, that is, a shape of a pixel aperture region in the pixel defining layer PDL where the light-emitting device is located) have to be met to use the color filter layer, and if the shapes of the subpixels in the display panel do not meet the requirements, diffraction of the display panel to ambient light will be aggravated. Referring to FIG. 1e, a schematic top view of a subpixel structure in a display panel in the existing art is shown. A red subpixel 302, a green subpixel 303, and a blue subpixel 301 in the display panel each have a rectangular or quasi-rectangular shape and arrangement. Under the external ambient light, lateral and longitudinal diffraction of the display panel to ambient light may be very clear, thereby severely affecting the appearance effect of the display panel when turned off.

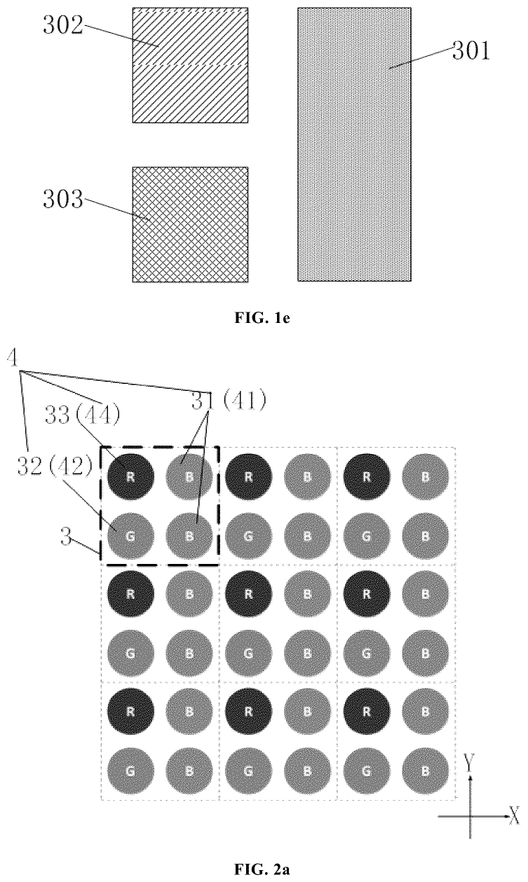

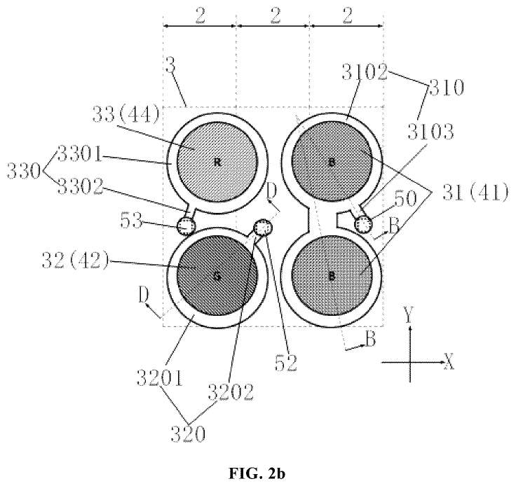

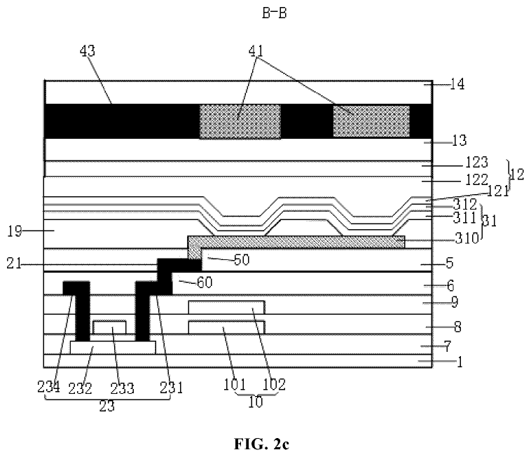

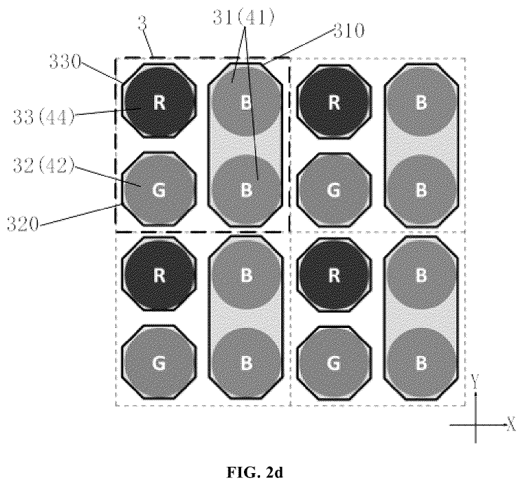

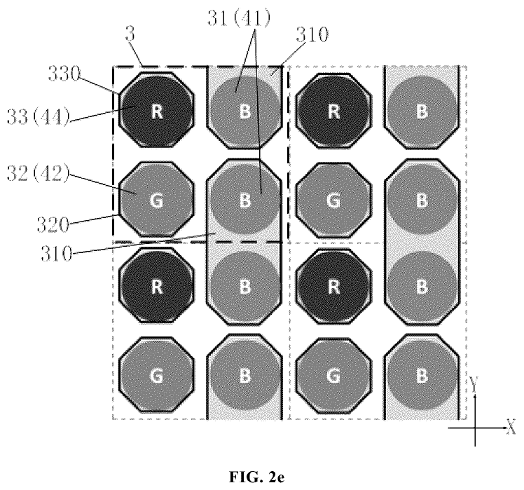

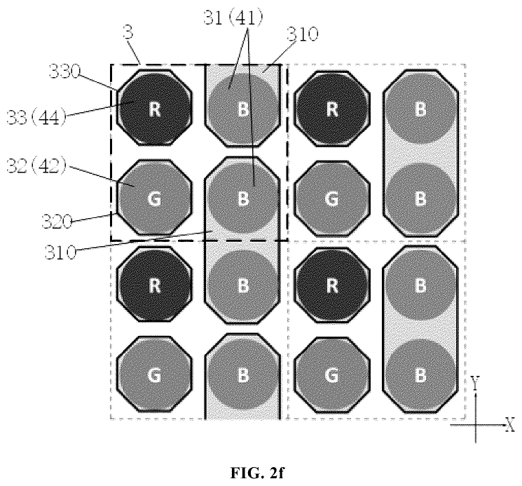

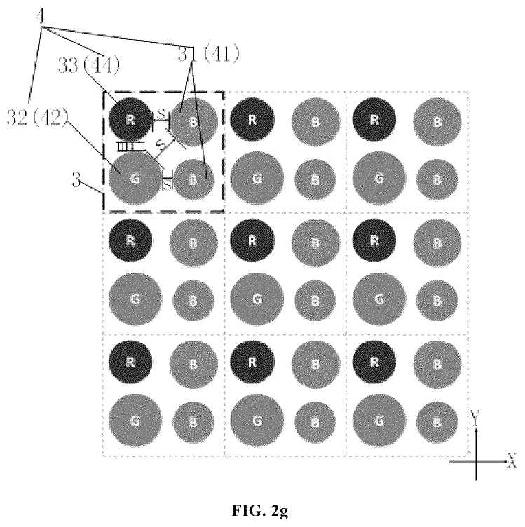

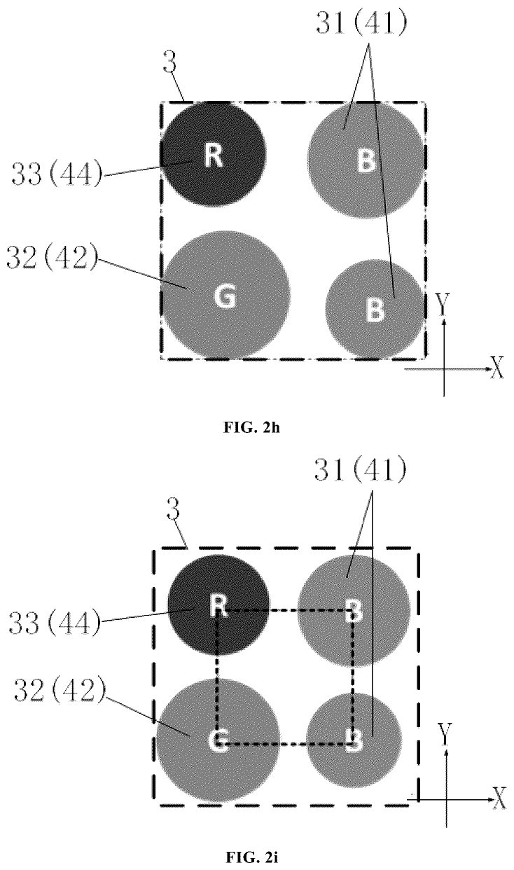

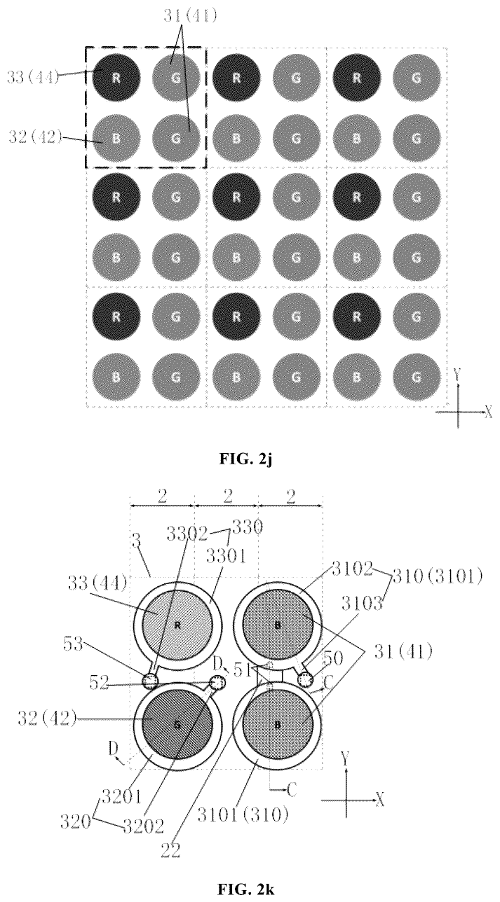

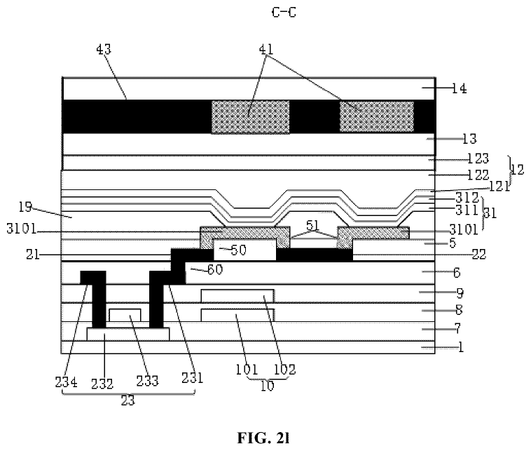

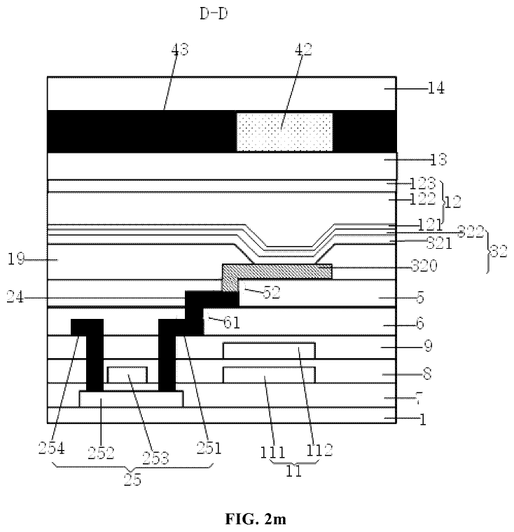

In order to solve the problem of aggravated diffraction of the display panel to ambient light caused by the color filter layer in the existing art, in a first aspect, an embodiment of the present disclosure provides a display panel. FIG. 2a shows a schematic structural top view of a display panel according to an embodiment of the present disclosure; FIG. 2b is a schematic structural top view of another display panel according to an embodiment of the present disclosure; and FIG. 2c is a schematic structural sectional view taken along line BB in FIG. 2b. The display panel includes a base 1, pixel circuits 2, an array of pixel units 3, and a color filter layer 4. The pixel circuits 2, the array of pixel units 3, and the color filter layer 4 are sequentially stacked on a side of the base 1. Each pixel unit 3 includes a first subpixel 31 and a second subpixel 32. The first subpixel 31 has an aperture ratio greater than an aperture ratio of the second subpixel 32, the first subpixel 31 has more apertures than the second subpixel 32 has, and the number of pixel circuit 2 for driving the first subpixel 31 is equal to the number of pixel circuit 2 for driving the second subpixel 32. The color filter layer 4 includes a first color filter 41 and a second color filter 42. An orthographic projection of the first color filter 41 on the base 1 covers an orthographic projection of the aperture in the first subpixel 31 on the base 1, and an orthographic projection of the second color filter 42 on the base 1 covers an orthographic projection of the aperture in the second subpixel 32 on the base 1. The orthographic projections of the first color filter 41 and the second color filter 42 on the base 1 each have a shape, at least part of edges of which are curved.

In some embodiments, the pixel unit 3 further includes a third subpixel 33. The first subpixel 31 has an aperture ratio greater than an aperture ratio of the third subpixel 33, the first subpixel 31 has more apertures than the third subpixel 33 has, and the number of pixel circuit 2 for driving the first subpixel 31 is equal to the number of pixel circuit 2 for driving the third subpixel 33. The color filter layer 4 further includes a third color filter 44. An orthographic projection of the third color filter 44 on the base 1 covers an orthographic projection of the aperture in the third subpixel 33 on the base 1; and the orthographic projection of the third color filter 44 on the base 1 has a shape, at least part of edges of which are curved.

In some embodiments, for the shape of the orthographic projection of the first color filter 41 on the base 1, a ratio of a dimension in a row direction of the array of pixel units 3 to a dimension in a column direction of the array of pixel units 3 is in a range of 0.8 to 1.2; for the shape of the orthographic projection of the second color filter 42 on the base 1, a ratio of a dimension in the row direction of the array of pixel units 3 to a dimension in the column direction of the array of pixel units 3 is in a range of 0.8 to 1.2; and for the shape of the orthographic projection of the third color filter 44 on the base 1, a ratio of a dimension in the row direction of the array of pixel units 3 to a dimension in the column direction of the array of pixel units 3 is in a range of 0.8 to 1.2.

In some embodiments, the shape of the orthographic projection of the first color filter 41 on the base 1 is symmetrical in both the row direction and the column direction of the array of pixel units 3; the shape of the orthographic projection of the second color filter 42 on the base 1 is symmetrical in both the row direction and the column direction of the array of pixel units 3; and the shape of the orthographic projection of the third color filter 44 on the base 1 is symmetrical in both the row direction and the column direction of the array of pixel units 3.

In some embodiments, the orthographic projection of the aperture in the first subpixel 31 on the base 1 has the same shape as the orthographic projection of the first color filter 41 on the base 1; the orthographic projection of the aperture in the second subpixel 32 on the base 1 has the same shape as the orthographic projection of the second color filter 42 on the base 1; and the orthographic projection of the aperture in the third subpixel 33 on the base 1 has the same shape as the orthographic projection of the third color filter 44 on the base 1.

In some embodiments, the orthographic projections of the first color filter 41, the second color filter 42, and the third color filter 44 on the base 1 each have a circular or quasi-circular shape. The quasi-circular shape includes, for example, an ellipse, a regular polygon with more than eight sides, a rounded polygon with more than eight sides, or the like.

In some embodiments, the first subpixel 31, the second subpixel 32, and the third subpixel 33 are organic light-emitting diode (OLED) devices. The first subpixel 31 includes a first anode 310, a first emission functional layer 311, and a first cathode 312. The first anode 310, the first emission functional layer 311, and the first cathode 312 are sequentially stacked away from the base 1, and when a current is generated between the first anode 310 and the first cathode 312, the first emission functional layer 311 emits light. The first emission functional layer 311 may include a hole injection layer, a hole transport layer, a first emission layer, an electron transport layer, and an electron injection layer sequentially stacked together. The second subpixel 32 includes a second anode 320, a second emission functional layer 321, and a second cathode 322. The second anode 320, the second emission functional layer 321, and the second cathode 322 are sequentially stacked away from the base 1, and when a current is generated between the second anode 320) and the second cathode 322, the second emission functional layer 321 emits light. The third subpixel 33 includes a third anode 330, a third emission functional layer, and a third cathode. The third anode, the third emission functional layer, and the third cathode are sequentially stacked away from the base 1, and when a current is generated between the third anode and the third cathode, the third emission functional layer emits light. The second emission functional layer 321 may include a hole injection layer, a hole transport layer, a second emission layer, an electron transport layer, and an electron injection layer sequentially stacked together. The third emission functional layer may include a hole injection layer, a hole transport layer, a third emission layer, an electron transport layer, and an electron injection layer sequentially stacked together. The first emission layer, the second emission layer, and the third emission layer emit different colors of light. In some embodiments, the first cathode 312, the second cathode 322, and the third cathode are disposed in the same layer and as a full layer throughout the display panel. In some embodiments, the hole injection layers of the first subpixel 31, the second subpixel 32, and the third subpixel 33 may be disposed in the same layer and as a full layer throughout the display panel; the hole transport layers of the first subpixel 31, the second subpixel 32, and the third subpixel 33 may be disposed in the same layer and as a full layer throughout the display panel; the electron transport layers of the first subpixel 31, the second subpixel 32, and the third subpixel 33 may be disposed in the same layer and as a full layer throughout the display panel; and the electron injection layers of the first subpixel 31, the second subpixel 32, and the third subpixel 33 may be disposed in the same layer and as a full layer throughout the display panel.

In some embodiments, the first color filter 41 has a same color as that of light emitted by the first subpixel 31, the second color filter 42 has a same color as that of light emitted by the second subpixel 32, and the third color filter 44 has a same color as that of light emitted by the third subpixel 33. The orthographic projection of the first color filter 41 on the base 1 covers an orthographic projection of the aperture in the first subpixel 31 on the base 1, so that the light emitted from the first subpixel 31 may exit after passing through the first color filter 41. The orthographic projection of the second color filter 42 on the base 1 covers an orthographic projection of the aperture in the second subpixel 32 on the base 1, so that the light emitted from the second subpixel 32 may exit after passing through the second color filter 42. The orthographic projection of the third color filter 44 on the base 1 has covers an orthographic projection of the aperture in the third subpixel 33 on the base 1, so that the light emitted from the third subpixel 33 may exit after passing through the third color filter 44. Therefore, the color saturation of the display image on the display panel is improved.

In some embodiments, the orthographic projections of the first color filter 41, the second color filter 42, and the third color filter 44 on the base 1 are not overlapped with each other; and the color filter layer 4 further includes a black matrix 43 having a pattern complementary to those of the first color filter 41, the second color filter 42, and the third color filter 44.

In this embodiment, the color filter layer 4 is used in the display panel in place of the polarizer in the existing art, which on the one hand, can reduce the light reflectivity of display panel, and on the other hand, can greatly improve the light transmittance of the display panel compared with the polarizer, thereby improving the display effect of the display panel. Meanwhile, the orthographic projections of the first color filter 41 and the second color filter 42 on the base 1 in the color filter layer 4 each have a shape, at least part of edges of which are curved, which can reduce diffraction of the display panel to ambient light, and thus improve the appearance effect of the display panel when turned off.

In some embodiments, the orthographic projections of the apertures in the first subpixel 31, in the second subpixel 32, and in the third subpixel 33 on the base 1 each have a circular or quasi-circular shape. In this manner, diffraction of the display panel to ambient light can be reduced, and thus the appearance effect of the display panel when turned off can be improved.

In some embodiments, a center of the orthographic projection of the first color filter 41 on the base 1 coincides with a center of the orthographic projection of the aperture in the first subpixel 31 on the base 1; a center of the orthographic projection of the second color filter 42 on the base 1 coincides with a center of the orthographic projection of the aperture in the second subpixel 32 on the base 1; and a center of the orthographic projection of the third color filter 44 on the base 1 coincides with a center of the orthographic projection of the aperture in the third subpixel 33 on the base 1.

In some embodiments, referring to FIGS. 2a and 2b, the pixel unit 3 includes at least two second subpixels 32 and at least one first subpixel 31. The first subpixel 31 has an aperture area greater than an aperture area of the second subpixel 32. Each second subpixel 32 has one aperture; and orthographic projections of apertures in the second subpixels 32 on the base 1 are not overlapped with each other. Each first subpixel 31 has at least two apertures; and orthographic projections of apertures in the first subpixel 31 on the base 1 are not overlapped with each other. The orthographic projections of the apertures in the first subpixel 31 and the second subpixel 32 on the base 1 are not overlapped with each other. The second subpixels 32 in the pixel unit 3 are arranged in a first direction Y, and the second subpixel 32 and the first subpixel 31 are arranged in a second direction X. The apertures in the first subpixel 31 in the pixel unit 3 are arranged in the first direction Y. The first direction Y is intersected with the second direction X.

In some embodiments, referring to FIGS. 2a and 2b, the first subpixel 31 has two apertures; the second subpixel 32 has one aperture; the third subpixel 33 has one aperture; in each pixel unit 3, the second subpixel 32 and the third subpixel 33 are arranged in the first direction Y, the second subpixel 32 and the first subpixel 31 are arranged in the second direction X; the third subpixel 33 and the first subpixel 31 are arranged in the second direction X; and the two apertures in the first subpixel 31 in the pixel unit 3 are arranged in the first direction Y; where the first direction Y is a column direction of the array of pixel units 3, and the second direction X is a row direction of the array of pixel units 3.

In some embodiments, refer to FIG. 2d, a schematic structural top view of yet another display panel according to an embodiment of the present disclosure is shown. The first subpixel 31 includes a first anode 310. An orthographic projection of the first anode 310 on the base 1 is within an orthographic projection of the pixel unit 3 to which the first anode belongs on the base 1. The orthographic projection of each aperture in the first subpixel 31 in the pixel unit 3 on the base 1 is within the orthographic projection of the first anode 310 on the base 1. With such arrangement of the first anodes 310, the aperture ratio of the pixel unit 3 is increased on one hand, and the display effect of the display panel is improved on the other hand.

In some embodiments, referring to FIG. 2d, the aperture in the second subpixel 32 and one aperture in the first subpixel 31 which are adjacent to each other and located in a first row, and the aperture in the third subpixel 33 and the other aperture in the first subpixel 31 which are adjacent to each other and located in a second row, constitute one pixel unit 3; and the first row is adjacent to the second row, the aperture in the second subpixel 32 and the aperture in the third subpixel 33 are located in the same column, and the one aperture in the first subpixel 31 and the other aperture in the first subpixel 31 are located in the same column.

In some embodiments, referring to FIG. 2e, a schematic structural top view of yet another display panel according to an embodiment of the present disclosure is shown. The first subpixel 31 includes a first anode 310. An orthographic projection of the first anode 310 on the base 1 extends from an orthographic projection of a first pixel unit 3 of two adjacent pixel units 3 in the first direction Y on the base 1 to an orthographic projection of a second pixel unit 3 of the two adjacent pixel units 3 on the base 1. Orthographic projections of an aperture in the first subpixel 31 in the first pixel unit 3 close to the second pixel unit 3 and an aperture in the first subpixel 31 in the second pixel unit 3 close to the first pixel unit 3 on the base 1 are within the orthographic projection of the first anode 310 on the base 1.

In some embodiments, referring to FIG. 2e, all first anodes 310 in the array of pixel units 3 have the same size and shape, and are arranged in the first direction Y and the second direction X to form an array. With such arrangement of the first anodes 310, the aperture ratio of the pixel unit 3 is increased on one hand, and the display effect of the display panel is improved on the other hand.

In some embodiments, referring to FIG. 2e, the aperture in the second subpixel 32 in a first row, the aperture in the third subpixel 33 and one aperture in the first subpixel 31 which are adjacent to each other and located in a second row, and the other aperture in the first subpixel 31 in a third row, constitute one pixel unit 3; and the first row, the second row, and the third row are sequentially arranged in the first direction Y, the aperture in the second subpixel 32 and the aperture in the third subpixel 33 are located in the same column, and the one aperture in the first subpixel 31 and the other aperture in the first subpixel 31 are located in the same column.

In some embodiments, referring to FIG. 2f, a schematic structural top view of yet another display panel according to an embodiment of the present disclosure is shown. The first subpixel 31 includes a first anode 310; the first direction Y is a column direction of the array of pixel units 3, and the second direction X is a row direction of the array of pixel units 3. For at least some odd columns of pixel units 3, an orthographic projection of the first anode 310 on the base 1 extends from an orthographic projection of a first pixel unit 3 of two adjacent pixel units 3 in the first direction Y on the base 1 to an orthographic projection of a second pixel unit 3 of the two adjacent pixel units 3 on the base 1. Accordingly, in the at least some odd columns of pixel units 3, orthographic projections of an aperture in the first subpixel 31 in the first pixel unit 3 close to the second pixel unit 3 and an aperture in the first subpixel 31 in the second pixel unit 3 close to the first pixel unit 3 on the base 1 are within the orthographic projection of the first anode 310 on the base 1. For at least some even columns of pixel units 3, an orthographic projection of the first anode 310 on the base 1 is within an orthographic projection of the pixel unit 3 to which the first anode belongs on the base 1. Accordingly, in the at least some even columns of pixel units 3, the orthographic projection of each aperture in the first subpixel 31 on the base 1 is within the orthographic projection of the corresponding first anode 310 on the base 1. With such arrangement of the first anodes 310, the aperture ratio of the pixel unit 3 is increased on one hand, and the display effect of the display panel is improved on the other hand.

In some embodiments, referring to FIG. 2f, in an odd column of the pixel units 3. the aperture in the second subpixel 32 in a first row, the aperture in the third subpixel 33 and one aperture in the first subpixel 31 which are adjacent to each other and located in a second row, and the other aperture in the first subpixel 31 in a third row, constitute one pixel unit 3; and the first row, the second row, and the third row are sequentially arranged in the first direction Y, the aperture in the second subpixel 32 and the aperture in the third subpixel 33 are located in the same column, and the one aperture in the first subpixel 31 and the other aperture in the first subpixel 31 are located in the same column. In an even column of the pixel units 3, the aperture in the second subpixel 32 and one aperture in the first subpixel 31 which are adjacent to each other and located in a first row, and the aperture in the third subpixel 33 and the other aperture in the first subpixel 31 which are adjacent to each other and located in a second row, constitute one pixel unit 3; and the first row is adjacent to the second row, the aperture in the second subpixel 32 and the aperture in the third subpixel 33 are located in the same column, and the one aperture in the first subpixel 31 and the other aperture in the first subpixel 31 are located in the same column.

In some embodiments, referring to FIGS. 2d, 2e and 2f, the second subpixel 32 includes a second anode 320. Orthographic projections of second anodes 320 of the second subpixels 32 in the pixel units 3 on the base 1 are spaced apart from each other. The orthographic projections of the second anode 320 and the first anode 310 on the base 1 are spaced apart from each other. The orthographic projection of the second anode 320 on the base 1 is within an orthographic projection of the pixel unit 3 to which the second anode belongs on the base 1. An orthographic projection of the aperture in the second subpixel 32 on the base 1 is within the orthographic projection of the second anode 320 of the second subpixel 32 on the base 1.

In some embodiments, referring to FIGS. 2b and 2k, the first subpixel 31 includes a first anode 310. The first anode 310 includes a first main body part 3102 and a first connection part 3103, and the first main body part 3102 is electrically connected to the first connection part 3103 which is further electrically connected to the pixel circuit 2 for the first subpixel 31.

In some embodiments, referring to FIGS. 2b and 2k, the second subpixel 32 includes a second anode 320. The second anode 320 includes a second body part 3201 and a second connection part 3202, and the second main body part 3201 is electrically connected to the second connection part 3202 which is further electrically connected to the pixel circuit 2 for the second subpixel 32.

In some embodiments, referring to FIGS. 2b and 2k, the third subpixel 33 includes a third anode 330. The third anode 330 includes a third main body part 3301 and a third connection part 3302, and the third main body part 3301 is electrically connected to the third connection part 3302 which is further electrically connected to the pixel circuit 2 for the third subpixel 33. An orthographic projection of the first main body part 3102 on the base 1 has a shape the same as or similar to the shape of the orthographic projection of the first color filter 41 on the base 1; an orthographic projection of the second main body part 3201 on the base 1 has a shape the same as or similar to the shape of the orthographic projection of the second color filter 42 on the base 1; and an orthographic projection of the third main body part 3301 on the base 1 has a shape the same as or similar to the shape of the orthographic projection of the third color filter 44 on the base 1.

In some embodiments, the orthographic projection of the first anode 310 on the base 1 has a circular or quasi-circular shape. The orthographic projection of the second anode 320 on the base 1 has a circular or quasi-circular shape. The orthographic projection of the third anode 330 on the base 1 has a circular or quasi-circular shape. In this manner, the aperture ratio of the subpixels can be ensured on the one hand, and diffraction of the display panel to ambient light can be reduced on the other hand, thereby improving the appearance effect of the display panel when turned off.

In some embodiments, the orthographic projection of the first color filter 41 on the base 1 falls within the orthographic projection of the first anode 310 on the base 1; the orthographic projection of the second color filter 42 on the base 1 falls within the orthographic projection of the second anode 320 on the base 1; and the orthographic projection of the third color filter 44 on the base 1 falls within the orthographic projection of the third anode 330 on the base 1. In this manner, the first color filter 41, the second color filter 42, and the third color filter 44, as well as the first anode 310, the second anode 320, and the third anode 330) can be manufactured to meet the process requirements.

In some embodiments, referring to FIG. 2g, a schematic structural top view of yet another display panel according to an embodiment of the present disclosure is shown. The first subpixel 31, the second subpixel 32 and the third subpixel 33 have different colors, and the apertures in the first subpixel 31 have different areas. A shortest distance s between aperture outlines of apertures in the first subpixel 31 and the second subpixel 32 adjacent to each other in the pixel unit 3 is greater than 10 μm; and a shortest distance m between aperture outlines of an aperture in the second subpixel 32 and an aperture in the third subpixel 33 adjacent to each other in the pixel unit 3 is greater than 10 μm. In this manner, the aperture ratio of the pixel unit 3 is increased on one hand, and the display effect of the display panel is improved on the other hand.

In some embodiments, referring to FIG. 2h, a schematic structural top view of yet another display panel according to an embodiment of the present disclosure is shown. An orthographic projection of a region where the pixel unit 3 is on the base 1 has a shape with a rectangular or quasi-rectangular outline. The quasi-rectangular shape refers to an irregular shape that resembles a rectangle. In this manner, the aperture ratio of the pixel unit 3 can be better increased, while the display effect of the display panel can be also improved.

In some embodiments, referring to FIG. 2h, outlines on the same side of the aperture in the second subpixel 32 and one aperture in the first subpixel 31 in the same row as the aperture in the second subpixel 32 in the pixel unit 3 are on a first straight line, outlines on the same side of the aperture in the third subpixel 33 and the other aperture in the first subpixel 31 in the same row as the aperture in the third subpixel 33 in the pixel unit 3 are on a second straight line, outlines on the same side of the aperture in the second subpixel 32 and the aperture in the third subpixel 33 in the same column as the aperture in the second subpixel 32 in the pixel unit 3 are on a third straight line, outlines on the same side of the one aperture in the first subpixel 31 and the other aperture in the first subpixel 31 in the same column as the one aperture in the first subpixel 31 in the pixel unit 3 are on a fourth straight line, the first straight line, the second straight line, the third straight line, and the fourth straight line are spliced to form a rectangle, and orthographic projections of the two apertures in the first subpixel 31, the aperture in the second subpixel 32, and the aperture in the third subpixel 33 in the pixel unit 3 on the base 1 are within an orthographic projection of the rectangle on the base 1.

In some embodiments, referring to FIG. 2i, a schematic structural top view of yet another display panel according to an embodiment of the present disclosure is shown. Centers of aperture patterns of the first subpixel 31 and the second subpixel 32 in the pixel unit 3 are connected to form a rectangular or quasi-rectangular shape. In this manner, the display effect of the display panel can be better improved, while the aperture ratio of the pixel unit 3 can be also increased.

In some embodiments, referring to FIG. 2i, centers of the aperture in the second subpixel 32 and one aperture in the first subpixel 31 in the same row as the aperture in the second subpixel 32 in the pixel unit 3 are on a first straight line, centers of the aperture in the third subpixel 33 and the other aperture in the first subpixel 31 in the same row as the aperture in the third subpixel 33 in the pixel unit 3 are on a second straight line, centers of the aperture in the second subpixel 32 and the aperture in the third subpixel 33 in the same column as the aperture in the second subpixel 32 in the pixel unit 3 are on a third straight line, centers of the one aperture in the first subpixel 31 and the other aperture in the first subpixel 31 in the same column as the one aperture in the first subpixel 31 in the pixel unit 3 are on a fourth straight line, and the first straight line, the second straight line, the third straight line, and the fourth straight line are spliced to form a rectangle.

In some embodiments, referring to FIGS. 2d, 2e, 2f, 2g, 2h and 2i, the first subpixel 31 includes a blue subpixel having two apertures; the second subpixel 32 includes a green subpixel; the third subpixel 33 includes a red subpixel; the first subpixel 31 has an aperture area greater than an aperture area of the second subpixel 32, and the second subpixel 32 has an aperture area greater than an aperture area of the third subpixel 33; a ratio of the aperture area of the second subpixel 32 to the aperture area of the first subpixel 31 in the pixel unit 3 is greater than or equal to 1:3 and less than 1:1; and a ratio of an area of an aperture in the third subpixel 33 to an area of any aperture in the first subpixel 31 in the pixel unit 3 is greater than or equal to 1:3 and less than 1:0. In this manner, the aperture ratio of the pixel unit 3 is increased on one hand, and a better color effect of the display panel is guaranteed on the other hand.

In some embodiments, referring to FIGS. 2d, 2e, 2f, 2g, 2h and 2i, the first color filter 41 includes a blue color filter, the second color filter 42 includes a green color filter, and the third color filter 44 includes a red color filter.

In some embodiments, referring to FIG. 2j, a schematic structural top view of yet another display panel according to an embodiment of the present disclosure is shown. The first subpixel 31 includes a green subpixel having two apertures; the second subpixel 32 includes a blue subpixel; the third subpixel 33 includes a red subpixel; the first subpixel 31 has an aperture area greater than an aperture area of the second subpixel 32, and the second subpixel 32 has an aperture area greater than an aperture area of the third subpixel 33; a ratio of the aperture area of the second subpixel 32 to the aperture area of the first subpixel 31 in the pixel unit 3 is greater than or equal to 1:3 and less than 1:1; and a ratio of an area of an aperture in the third subpixel 33 to an area of any aperture in the first subpixel 31 in the pixel unit 3 is greater than or equal to 1:3 and less than 1:0. In this manner, the aperture ratio of the pixel unit 3 is increased on one hand, and a better color effect of the display panel is guaranteed on the other hand.

In some embodiments, referring to FIG. 2j, the first color filter 41 includes a green color filter, the second color filter 42 includes a blue color filter, and the third color filter 44 includes a red color filter.

In some embodiments, referring to FIGS. 2b and 2c, the first subpixel 31 includes a first anode 310. Orthographic projections of the apertures in the first subpixel 31 in the pixel unit 3 on the base 1 are not overlapped with each other. First anodes 310 corresponding to both apertures in the first subpixel 31 in the pixel unit 3 are integrally connected, and the orthographic projection of each aperture in the first subpixel 31 on the base 1 is within the orthographic projection of the corresponding first anode 310 on the base 1.

In some embodiments, referring to FIGS. 2b and 2c, the pixel circuit 2 includes a first connecting electrode 21 on a side of the first anode 310 close to the base 1. A first planarization layer 5 is between the first connecting electrode 21 and the first anode 310. An orthographic projection of the first connecting electrode 21 on the base 1 is at least partially overlapped with the orthographic projection of the first anode 310 on the base 1, and the first planarization layer 5 is provided with a first via 50 in an overlap region of the orthographic projections, through which the first anode 310 is connected to the first connecting electrode 21. An orthographic projection of the first via 50 on the base 1 is located in an overlap region of the orthographic projections of the first connecting electrode 21 and the first anode 310, and the orthographic projection of the first via 50 on the base 1 is not overlapped with the orthographic projections of the apertures in the first subpixel 31 on the base.

In some embodiments, referring to FIG. 2k, a schematic structural top view of yet another display panel according to an embodiment of the present disclosure is shown. FIG. 2l is a schematic structural sectional view taken along line CC in FIG. 2k. The first subpixel 31 includes a first anode 310. The first anode 310 includes a plurality of sub-electrodes 3101 distributed at intervals. Orthographic projections of the apertures in the first subpixel 31 in the pixel unit 3 on the base 1 are not overlapped with each other. The orthographic projections of the apertures in the first subpixel 31 on the base 1 in the pixel unit 3 correspond to different sub-electrodes 3101, respectively, and the orthographic projection of each aperture in the first subpixel 31 on the base 1 is within an orthographic projection of the corresponding sub-electrode 3101 on the base 1.

In some embodiments, referring to FIGS. 2k and 2l, the pixel circuit 2 includes a first connecting electrode 21 and a second connecting electrode 22 arranged in the same layer. The first connecting electrode 21 and the second connecting electrode 22 are on a side of the first anode 310 close to the base 1. A first planarization layer 5 is between the first anode 310 and the first and second connecting electrodes 21, 22. An orthographic projection of the first connecting electrode 21 on the base 1 is at least partially overlapped with an orthographic projection of one sub-electrode 3101 of the first anode 310 on the base 1, and the one sub-electrode 3101 of the first anode 310 is connected to the first connecting electrode 21 through a first via 50 in the first planarization layer 5. An orthographic projection of the first via 50 on the base 1 is located in an overlap region of the orthographic projections of the first connecting electrode 21 and the one sub-electrode 3101 of the first anode 310, and the orthographic projection of the first via 50 on the base 1 is not overlapped with the orthographic projections of the apertures in the first subpixel 31 on the base 1. An orthographic projection of the second connecting electrode 22 on the base 1 is at least partially overlapped with orthographic projections of any two adjacent sub-electrodes 3101 of the first anode 310 on the base 1, and the two adjacent sub-electrodes 3101 of the first anode 310 are connected to the second connecting electrode 22 through second vias 51 in the first planarization layer 5, respectively. An orthographic projection of the second vias 51 on the base 1 is located in an overlap region of the orthographic projections of the second connecting electrode 22 and the two adjacent sub-electrodes 3101 of the first anode 310, and the orthographic projection of the second via 51 on the base 1 is not overlapped with the orthographic projections of the apertures in the first subpixel 31 on the base 1.

In some embodiments, referring to FIGS. 2k and 2l, the orthographic projection of the second connecting electrode 22 on the base 1 is located between orthographic projections of any two adjacent sub-electrodes 3101 of the first anode 310 on the base 1, and at least a part of the orthographic projection of the second connecting electrode 22 on the base 1 is not overlapped with the orthographic projections of the two adjacent sub-electrodes 3101 of the first anode 310 on the base 1.

In some embodiments, referring to FIGS. 2k and 2l, the orthographic projections of the first via 50 and the second via 51 on the base 1 are within an orthographic projection of the pixel circuit 2 for the first subpixel 31 on the base 1.

In some embodiments, referring to FIGS. 2b and 2c and FIGS. 2k and 2l, the pixel circuit 2 further includes a first drive transistor 23 on a side of the first connecting electrode 21 close to the base 1, and a second planarization layer 6 is between the first drive transistor 23 and the first connecting electrode 21. The orthographic projection of the first connecting electrode 21 on the base 1 is at least partially overlapped with an orthographic projection of a first electrode 231 of the first drive transistor 23 on the base 1, and the first connecting electrode 21 is connected to the first electrode 231 of the first drive transistor 23 through a third via 60 in the second planarization layer 6. An orthographic projection of the third via 60 on the base 1 is located in an overlap region of the orthographic projections of the first connecting electrode 21 and the first electrode 231 of the first drive transistor 23, and the orthographic projection of the third via 60 on the base 1 is not overlapped with the orthographic projections of the apertures in the first subpixel 31 on the base 1.

In some embodiments, the first drive transistor 23 further includes an active layer 232, a gate 233, and a second electrode 234. The gate 233 is on a side of the active layer 232 away from the base 1, and a first gate insulation layer 7 is disposed between the gate 233 and the active layer 232. The second electrode 234 and the first electrode 231 are disposed in the same layer, the second electrode 234 and the first electrode 231 are disposed on a side of the gate 233 away from the base 1, and a second gate insulation layer 8 and an intermediate dielectric layer 9 are disposed between the gate 233 and the first and second electrodes 231, 234. In addition, the pixel circuit 2 further includes a first capacitor 10. A first plate 101 of the first capacitor 10 and the gate 233 are disposed in the same layer, a second plate 102 of the first capacitor 10 is on a side of the first plate 101 away from the base 1, and the first plate 101 and the second plate 102 are insulated by the second gate insulation layer 8.

In some embodiments, referring to FIG. 2m, a schematic structural sectional view taken along line DD in FIGS. 2b and 2k is shown. The second subpixel 32 includes a second anode 320. The pixel circuit 2 further includes a third connecting electrode 24 in the same layer as the first connecting electrode 21. The third connecting electrode 24 is on a side of the second anode 320 close to the base 1. The first planarization layer 5 further extends between the third connecting electrode 24 and the second anode 320. An orthographic projection of the third connecting electrode 24 on the base 1 is at least partially overlapped with the orthographic projection of the second anode 320 on the base 1, and the second anode 320 is connected to the third connecting electrode 24 through a fourth via 52 in the first planarization layer 5. An orthographic projection of the fourth via 52 on the base 1 is located in an overlap region of the orthographic projections of the third connecting electrode 24 and the second anode 320, and the orthographic projection of the fourth via 52 on the base 1 is not overlapped with the orthographic projection of the aperture in the second subpixel 32 on the base 1.

In some embodiments, referring to FIGS. 2b and 2k, the third subpixel 33 includes a third anode 330. The pixel circuit further includes a fourth connecting electrode in the same layer as the first connecting electrode. The fourth connecting electrode is on a side of the third anode 330 close to the base. The first planarization layer further extends between the fourth connecting electrode and the third anode 330. An orthographic projection of the fourth connecting electrode on the base is at least partially overlapped with the orthographic projection of the third anode 330 on the base, and the first planarization layer is further provided with a fifth via 53 in an overlap region of the orthographic projections, through which the third anode 330 is connected to the fourth connecting electrode. An orthographic projection of the fifth via 53 on the base is not overlapped with the orthographic projection of the aperture in the third subpixel 33 on the base.

In some embodiments, referring to FIGS. 2b and 2k, the orthographic projection of the fourth via 52 on the base 1 is within an orthographic projection of the pixel circuit 2 for the second subpixel 32 on the base 1; and the orthographic projection of the fifth via 53 on the base is within an orthographic projection of the pixel circuit 2 for the third subpixel 33 on the base.

In some embodiments, referring to FIG. 2m, the pixel circuit 2 further includes a second drive transistor 25 on a side of the third connecting electrode 24 close to the base 1, and the second planarization layer 6 further extends between the second drive transistor 25 and the third connecting electrode 24. The orthographic projection of the third connecting electrode 24 on the base 1 is at least partially overlapped with an orthographic projection of a first electrode 251 of the second drive transistor 25 on the base 1, and the third connecting electrode 24 is connected to the first electrode 251 of the second drive transistor 25 through a sixth via 61 in the second planarization layer 6. An orthographic projection of the sixth via 61 on the base 1 is located in an overlap region of the orthographic projections of the third connecting electrode 24 and the first electrode 251 of the second drive transistor 25, and the orthographic projection of the sixth via 61 on the base 1 is not overlapped with the orthographic projection of the aperture in the second subpixel 32 on the base 1.

In some embodiments, the pixel circuit further includes a third drive transistor (not shown). The third drive transistor is on a side of the fourth connecting electrode close to the base, and the second planarization layer further extends between the third drive transistor and the fourth connecting electrode. The orthographic projection of the fourth connecting electrode on the base is at least partially overlapped with an orthographic projection of a first electrode of the third drive transistor on the base, and the second planarization layer is further provided with a seventh via in an overlap region of the orthographic projections, through which the fourth connecting electrode is connected to the first electrode of the third drive transistor. An orthographic projection of the seventh via on the base is not overlapped with the orthographic projection of the aperture in the third subpixel on the base.

In some embodiments, the second drive transistor 25 further includes an active layer 252, a gate 253, and a second electrode 254. The gate 253 is on a side of the active layer 252 away from the base 1, and a first gate insulation layer 7 is disposed between the gate 253 and the active layer 252. The second electrode 254 and the first electrode 251 are disposed in the same layer, the second electrode 254 and the first electrode 251 are disposed on a side of the gate 253 away from the base 1, and a second gate insulation layer 8 and an intermediate dielectric layer 9 are disposed between the gate 253 and the first and second electrodes 251, 254. In addition, the pixel circuit 2 further includes a second capacitor 11. A first plate 111 of the second capacitor 11 and the gate 253 are disposed in the same layer, a second plate 112 of the second capacitor 11 is on a side of the first plate 111 away from the base 1, and the first plate 111 and the second plate 112 are insulated by the second gate insulation layer 8.

In some embodiments, referring to FIGS. 2b and 2k, the pixel circuit 2 for the third subpixel 33, the pixel circuit 2 for the second subpixel 32, and the pixel circuit 2 for the first subpixel 31 in the pixel unit 3 are distributed in sequence along the second direction X. That is, in this embodiment, the pixel circuits 2 for the red, green and blue subpixels in the pixel unit 3 are distributed in sequence along the second direction X.

In some embodiments, referring to FIGS. 2c, 2l and 2m, the display panel further includes a pixel defining layer 19 on a side of the first planarization layer 5 away from the base 1. The pixel defining layer 19 has a plurality of pixel apertures in one-to-one correspondence with the first subpixel 31, the second subpixel 32, and the third subpixel 33. The first anode 310, the second anode 320 and the third anode 330 are located between the pixel defining layer 19 and the first planarization layer 5, and portions of the first anode 310, the second anode 320, and the third anode 330 are exposed through the pixel apertures.

In some embodiments, referring to FIGS. 2c, 2l and 2m, the display panel further includes an encapsulation layer 12, a touch layer 13, and a cover plate 14. The encapsulation layer 12 and the touch layer 13 are located between the array of pixel units 3 and the color filter layer 4, and sequentially stacked on a side of the array of pixel units 3 close to the color filter layer 4. The cover plate 14 is on a side of the color filter layer 4 away from the base 1.

In some embodiments, the encapsulation layer 12 includes a first inorganic encapsulation layer 121, an organic encapsulation layer 122, and a second inorganic encapsulation layer 123 sequentially stacked. The encapsulation layer 12 encapsulates the array of pixel units 3 to prevent moisture and/or oxygen in the external environment from corroding the subpixels. Both the first inorganic encapsulation layer 121 and the second inorganic encapsulation layer 123 may be made of an inorganic material with high compactness, and the organic encapsulation layer 122 may be made of an organic polymer resin material.

In some embodiments, the touch layer 13 is directly prepared on a side of the encapsulation layer 12 away from the base 1 for touch control of the display panel. The cover plate 14 may be made of a glass or resin material to protect the color filter layer 4 and the whole display panel.

In this embodiment, a color filter layer 4 is used in the display panel in place of the polarizer in the existing art, which on the one hand, can reduce the light reflectivity of display panel, and on the other hand, can greatly improve the light transmittance of the display panel compared with the polarizer, thereby improving the display effect of the display panel. Meanwhile, the orthographic projections of the first color filter 41 and the second color filter 42 on the base 1 in the color filter layer 4 each have a circular or quasi-circular shape, which can reduce diffraction of the display panel to ambient light, and thus improve the appearance effect of the display panel when turned off.

An embodiment of the present disclosure further provides a display apparatus, including the display panel according to any one of the above embodiments.

By adopting the display panel according to any one of the above embodiments, the light reflectivity of the display apparatus can be reduced on one hand, and the light transmittance of the display apparatus can be greatly improved on the other hand, thereby improving the display effect of the display apparatus. Meanwhile, diffraction of the display apparatus to ambient light can be reduced, and thus the appearance effect of the display apparatus when turned off can be improved.

The display apparatus in the embodiments of the present disclosure may be any product or component with a display function, such as an OLED panel, an OLED television, an OLED billboard, a monitor, a mobile phone, a navigator, or the like.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A display panel, comprising a base, pixel circuits, an array of pixel units, and a color filter layer, wherein
the pixel circuits, the array of pixel units, and the color filter layer are sequentially stacked on a side of the base;
each pixel unit comprises a first subpixel and a second subpixel, the first subpixel has an aperture ratio greater than an aperture ratio of the second subpixel, the first subpixel has more apertures than the second subpixel has, and the number of pixel circuit for driving the first subpixel is equal to the number of pixel circuit for driving the second subpixel;
the color filter layer comprises a first color filter and a second color filter, an orthographic projection of the first color filter on the base covers an orthographic projection of the aperture in the first subpixel on the base, and an orthographic projection of the second color filter on the base covers an orthographic projection of the aperture in the second subpixel on the base; and
the orthographic projections of the first color filter and the second color filter on the base each have a shape, at least part of edges of which are curved.

2. The display panel according to claim 1, wherein the pixel unit further comprises a third subpixel,
the first subpixel has an aperture ratio greater than an aperture ratio of the third subpixel, the first subpixel has more apertures than the third subpixel has, and the number of pixel circuit for driving the first subpixel is equal to the number of pixel circuit for driving the third subpixel;
the color filter layer further comprises a third color filter, and an orthographic projection of the third color filter on the base covers an orthographic projection of the aperture in the third subpixel on the base; and
the orthographic projection of the third color filter on the base has a shape, at least part of edges of which are curved.

3. The display panel according to claim 2, wherein for the shape of the orthographic projection of the first color filter on the base, a ratio of a dimension in a row direction of the array of pixel units to a dimension in a column direction of the array of pixel units is in a range of 0.8 to 1.2;
for the shape of the orthographic projection of the second color filter on the base, a ratio of a dimension in the row direction of the array of pixel units to a dimension in the column direction of the array of pixel units is in a range of 0.8 to 1.2; and
for the shape of the orthographic projection of the third color filter on the base, a ratio of a dimension in the row direction of the array of pixel units to a dimension in the column direction of the array of pixel units is in a range of 0.8 to 1.2.

4. The display panel according to claim 2, wherein the shape of the orthographic projection of the first color filter on the base is symmetrical in both a row direction and a column direction of the array of pixel units;
the shape of the orthographic projection of the second color filter on the base is symmetrical in both the row direction and the column direction of the array of pixel units; and
the shape of the orthographic projection of the third color filter on the base is symmetrical in both the row direction and the column direction of the array of pixel units.

5. The display panel according to claim 2, wherein the orthographic projection of the aperture in the first subpixel on the base has the same shape as the orthographic projection of the first color filter on the base;
the orthographic projection of the aperture in the second subpixel on the base has the same shape as the orthographic projection of the second color filter on the base; and
the orthographic projection of the aperture in the third subpixel on the base has the same shape as the orthographic projection of the third color filter on the base.

6. The display panel according to claim 5, wherein the first subpixel has two apertures;
the second subpixel has one aperture;
the third subpixel has one aperture;
in each pixel unit, the second subpixel and the third subpixel are arranged in a first direction, the second subpixel and the first subpixel are arranged in a second direction, and the third subpixel and the first subpixel are arranged in the second direction;
in each pixel unit, the two apertures in the first subpixel are arranged in the first direction; and
the first direction is a column direction of the array of pixel units, and the second direction is a row direction of the array of pixel units.

7. The display panel according to claim 6, wherein the aperture in the second subpixel and one aperture in the first subpixel are adjacent to each other and located in a first row, and the aperture in the third subpixel and the other aperture in the first subpixel are adjacent to each other and located in a second row; and
the first row is adjacent to the second row, the aperture in the second subpixel and the aperture in the third subpixel are located in the same column, and the one aperture in the first subpixel and the other aperture in the first subpixel are located in the same column.

8. The display panel according to claim 6, wherein the aperture in the second subpixel is in a first row, the aperture in the third subpixel and one aperture in the first subpixel are adjacent to each other and located in a second row, and the other aperture in the first subpixel is in a third row; and
the first row, the second row, and the third row are sequentially arranged in the first direction, the aperture in the second subpixel and the aperture in the third subpixel are located in the same column, and the one aperture in the first subpixel and the other aperture in the first subpixel are located in the same column.

9. The display panel according to claim 6, wherein in an odd column of the pixel units, the aperture in the second subpixel is in a first row, the aperture in the third subpixel and one aperture in the first subpixel are adjacent to each other and located in a second row, and the other aperture in the first subpixel is in a third row; and
the first row, the second row, and the third row are sequentially arranged in the first direction, the aperture in the second subpixel and the aperture in the third subpixel are located in the same column, and the one aperture in the first subpixel and the other aperture in the first subpixel are located in the same column;
in an even column of the pixel units, the aperture in the second subpixel and one aperture in the first subpixel are adjacent to each other and located in a first row, and the aperture in the third subpixel and the other aperture in the first subpixel are adjacent to each other and located in a second row; and
the first row is adjacent to the second row, the aperture in the second subpixel and the aperture in the third subpixel are located in the same column, and the one aperture in the first subpixel and the other aperture in the first subpixel are located in the same column.

10. The display panel according to claim 6, wherein the first subpixel comprises a first anode;
the first anode comprises a first main body part and a first connection part, and the first main body part is electrically connected to the first connection part which is further electrically connected to the pixel circuit for the first subpixel;
the second subpixel comprises a second anode;
the second anode comprises a second body part and a second connection part, and the second main body part is electrically connected to the second connection part which is further electrically connected to the pixel circuit for the second subpixel;
the third subpixel comprises a third anode;
the third anode comprises a third main body part and a third connection part, and the third main body part is electrically connected to the third connection part which is further electrically connected to the pixel circuit for the third subpixel;
an orthographic projection of the first main body part on the base has a shape the same as or similar to the shape of the orthographic projection of the first color filter on the base;
an orthographic projection of the second main body part on the base has a shape the same as or similar to the shape of the orthographic projection of the second color filter on the base; and
an orthographic projection of the third main body part on the base has a shape the same as or similar to the shape of the orthographic projection of the third color filter on the base.

11. The display panel according to claim 2, wherein the first subpixel, the second subpixel, and the third subpixel are different in color,
the apertures in the first subpixel have different areas;
a shortest distance between aperture outlines of the aperture in the first subpixel and the aperture in the second subpixel adjacent to each other in the pixel unit is greater than 10 μm; and
a shortest distance between aperture outlines of the aperture in the second subpixel and the aperture in the third subpixel adjacent to each other in the pixel unit is greater than 10 μm.

12. The display panel according to claim 7, wherein outlines on the same side of the aperture in the second subpixel and one aperture in the first subpixel in the same row as the aperture in the second subpixel in the pixel unit are on a first straight line,
outlines on the same side of the aperture in the third subpixel and the other aperture in the first subpixel in the same row as the aperture in the third subpixel in the pixel unit are on a second straight line,
outlines on the same side of the aperture in the second subpixel and the aperture in the third subpixel in the same column as the aperture in the second subpixel in the pixel unit are on a third straight line,
outlines on the same side of the one aperture in the first subpixel and the other aperture in the first subpixel in the same column as the one aperture in the first subpixel in the pixel unit are on a fourth straight line,
the first straight line, the second straight line, the third straight line, and the fourth straight line are spliced to form a rectangle, and
orthographic projections of the two apertures in the first subpixel, the aperture in the second subpixel, and the aperture in the third subpixel in the pixel unit on the base are within an orthographic projection of the rectangle on the base.

13. The display panel according to claim 7, wherein centers of the aperture in the second subpixel and one aperture in the first subpixel in the same row as the aperture in the second subpixel in the pixel unit are on a first straight line,
centers of the aperture in the third subpixel and the other aperture in the first subpixel in the same row as the aperture in the third subpixel in the pixel unit are on a second straight line,
centers of the aperture in the second subpixel and the aperture in the third subpixel in the same column as the aperture in the second subpixel in the pixel unit are on a third straight line,
centers of the one aperture in the first subpixel and the other aperture in the first subpixel in the same column as the one aperture in the first subpixel in the pixel unit are on a fourth straight line, and
the first straight line, the second straight line, the third straight line, and the fourth straight line are spliced to form a rectangle.

14. The display panel according to claim 2, wherein the first subpixel comprises a blue subpixel;
the second subpixel comprises a green subpixel;
the third subpixel comprises a red subpixel;
the first subpixel has an aperture area greater than an aperture area of the second subpixel, and the second subpixel has an aperture area greater than an aperture area of the third subpixel;
a ratio of the aperture area of the second subpixel to the aperture area of the first subpixel in the pixel unit is greater than or equal to 1:3 and less than 1:1; and
a ratio of an area of the aperture in the third subpixel to an area of any aperture in the first subpixel in the pixel unit is greater than or equal to 1:3 and less than 1:0.

15. The display panel according to claim 2, wherein the first subpixel comprises a green subpixel;
the second subpixel comprises a blue subpixel;
the third subpixel comprises a red subpixel;
the first subpixel has an aperture area greater than an aperture area of the second subpixel, and the second subpixel has an aperture area greater than an aperture area of the third subpixel;
a ratio of the aperture area of the second subpixel to the aperture area of the first subpixel in the pixel unit is greater than or equal to 1:3 and less than 1:1; and
a ratio of an area of the aperture in the third subpixel to an area of any aperture in the first subpixel in the pixel unit is greater than or equal to 1:3 and less than 1:0.

16. The display panel according to claim 6, wherein the first subpixel comprises a first anode; and
the first anode corresponds to all apertures in the first subpixel in the pixel unit and has a one-piece structure.

17. The display panel according to claim 16, wherein the pixel circuit comprises a first connecting electrode,
the first connecting electrode is on a side of the first anode close to the base; a first planarization layer is between the first connecting electrode and the first anode;
an orthographic projection of the first connecting electrode on the base is at least partially overlapped with an orthographic projection of the first anode on the base, and the first planarization layer is provided with a first via in an overlap region of the orthographic projections, and the first anode is connected to the first connecting electrode through the first via; and
an orthographic projection of the first via on the base is not overlapped with the orthographic projection of the aperture in the first subpixel on the base.

18. The display panel according to claim 6, wherein the first subpixel comprises a first anode;
the first anode comprises a plurality of sub-electrodes distributed at intervals; and
orthographic projections of the apertures in the first subpixel in the pixel unit on the base are respectively within orthographic projections of different sub-electrodes on the base.

19. The display panel according to claim 18, wherein the pixel circuit comprises a first connecting electrode and a second connecting electrode,
the first connecting electrode and the second connecting electrode are in the same layer;
the first connecting electrode and the second connecting electrode are on a side of the first anode close to the base; a first planarization layer is between the first anode and the first and second connecting electrodes;
an orthographic projection of the first connecting electrode on the base is at least partially overlapped with an orthographic projection of one sub-electrode of the first anode on the base, and the first planarization layer is provided with a first via in an overlap region of the orthographic projections, and the one sub-electrode of the first anode is connected to the first connecting electrode through the first via;
an orthographic projection of the first via on the base is not overlapped with the orthographic projection of the aperture in the first subpixel on the base;
an orthographic projection of the second connecting electrode on the base is at least partially overlapped with orthographic projections of any two adjacent sub-electrodes of the first anode on the base, and the first planarization layer is further provided with a second via in an overlap region of the orthographic projections, and the two adjacent sub-electrodes of the first anode are respectively connected to the second connecting electrode through the second via; and
an orthographic projection of the second via on the base is not overlapped with the orthographic projection of the aperture in the first subpixel on the base.

20-27. (canceled)

28. A display apparatus, comprising the display panel according to claim 1.
